(19) United States
(12) Patent Application Publication
(10) Pub. No.: US 2006/0284699 A1
(43) Pub. Date: Dec. 21, 2006

(54) Device for connecting a coaxial line to a coplanar line

(76) Inventor: Claus-Jörg Weiske, Furstenfelddbruck (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 10/573,672

(22) PCT Filed: Sep. 27, 2004
(86) PCT No.: PCT/EP04/52322

§ 371 Date: Mar. 24, 2006

(30) Foreign Application Priority Data
Sep. 29, 2003 (DE) 10345218.4

(51) Int. Cl. H03H 7/38

(52) U.S. Cl. 333/33

(57) ABSTRACT

The coaxial line comprises a coaxial inner conductor and a first dielectric layer encompassing the coaxial inner conductor and which is surrounded by a coaxial outer conductor. The coplanar line comprises a second dielectric layer with a coplanar inner conductor and a first and second coplanar outer conductor applied to the front side thereof and with a metallization layer followed by a substrate carrier layer on the rear side thereof. The first and second coplanar outer conductors are separated from the coplanar inner conductor by the second dielectric layer and the coaxial inner conductor is connected to the coplanar inner conductor and the coaxial outer conductor is connected to the first and second coplanar outer conductors. When high bit rate data signals are transmitted via the connecting point of the coaxial line and the coplanar line, the capacitative power is increased and undesirable reflections occur. In order to avoid this, a recess is provided in the metallization layer, beginning at the point of connection between the coaxial line and the coplanar line and extending in an approximately symmetrical manner with respect to the coplanar inner conductor, tapering in the direction of the coplanar inner conductor as the distance from the point of connection increases.

### CROSS REFERENCE TO RELATED APPLICATIONS

This application is the US National Stage of International Application No. PCT/EP2004/052322, filed Sep. 27, 2004 and claims the benefit thereof. The International Application claims the benefits of German application No. 10345218.4 filed Sep. 29, 2003, both of the applications are incorporated by reference herein in their entirety.

### FIELD OF THE INVENTION

The invention relates to a device for connecting a coaxial line to a coplanar line for the transmission of high bit rate data signals, wherein the coaxial line comprises a coaxial inner conductor and a first dielectric layer encompassing the coaxial inner conductor, the dielectric layer being surrounded by a coaxial outer conductor. The coplanar line comprises a second dielectric layer, applied to the front face of which are a coplanar inner conductor and a first and second coplanar outer conductor, and the rear face of which comprises a metallization layer followed by a substrate carrier layer. The first and second coplanar outer conductors are separated from the coplanar inner conductor by the second dielectric layer and the coaxial inner conductor is connected to the coplanar inner conductor and the coaxial outer conductor is connected to the first and second coplanar outer conductors.

### BACKGROUND OF THE INVENTION

A simple embodiment for connecting a coaxial line, such as a coaxial plug for example, having a grounded coplanar line (“Grounded Coplanar Waveguide”, GCPW) is shown for instance in FIG. 1. The coaxial plug 1 comprises a coaxial inner conductor 2, a first dielectric layer 3 and a coaxial outer conductor 4. The coplanar line 5 consists of a conductor layer (6, 7, 8), followed by a second dielectric layer 9, a metallization layer 10 and a substrate carrier layer 11. The conductor layer (6, 7, 8) consists of a coplanar inner conductor 6 and a first and second coplanar outer conductor (7, 8) which are separated from the coplanar inner conductor 6 by the second dielectric layer 9. The coaxial inner conductor 2 of the coaxial plug 1 is connected to the coplanar inner conductor 6 of the coplanar line 5 and the coaxial outer conductor 4 of the coaxial plug 1 is connected to the first and the second coplanar outer conductor 7, 8 of the coplanar line 5 (“earth potential”) and to the metallization layer 10 (likewise “earth potential”) that is located on the rear face of the second dielectric layer 9. The second dielectric layer 9 of the coplanar line 5 is usually applied over the metallization layer 10 on a metallic substrate carrier layer 11, which serves both for mechanical stabilization and also for heat dissipation and heat distribution from components provided on the second dielectric layer 9.

When transmitting high bit rate data signals, having a data rate of greater than 40 Gbit/s, for example, over the grounded coplanar line, the dispersion in the waveguide should be kept as low as possible. This is achieved by a tight connection of the first and second coplanar outer conductor 7, 8 to the coplanar inner conductor 6:—the width of the coplanar inner conductor 6 is minimal, the distance between the coplanar inner conductor 6 and the coplanar outer conductors 7, 8 is short and the thickness of the second dielectric layer 9 is also minimal.

At the point of connection between the coaxial inner conductor 2 and the coplanar line 5, the geometry of the coaxial plug 1 requires a minimal width of the circumference of the coplanar inner conductor 6. This is achieved by a continuous widening of the coplanar inner conductor 6 and of the distances between the coplanar inner conductor 6 and the first and the second coplanar outer conductors 7, 8 in the vicinity of the point of contact. A possible form of achieving the geometry described is shown in FIG. 2 for instance.

This widening can lead to an undesirable increase in the capacitive wire load and therefore to an undesirable local reflection, which, at frequencies greater than 40 GHz, results in interference with the transmission and reflection properties at the point of connection. A further increase in the unit-area capacitance and hence an increase in the local reflection occurs at the point of connection between the coaxial line and the coplanar line where the relative dielectric constants of the first and second dielectric layer 3, 9 are different. In communication devices for the transmission of high bit rate data signals, usually coaxial plugs 1 having a first dielectric layer 3 with a low relative dielectric constant, e.g. air (εᵣ=1) are used and on the other hand, for the coplanar line 5, a second dielectric layer 9 with a relatively high relative dielectric constant, e.g. ceramic (εᵣ=10) is used.

Consequently, for the transmission of high bit rate data signals, compensation of the above capacitive line load is required directly at the point where it occurs. Compensation by means of circuitry arrangements at a different point along the transmission path, as is usual in narrow band applications, does not produce the desired effect.

For this purpose, U.S. Pat. No. 5,404,117 discloses a device for connecting a coaxial plug to a coplanar line, wherein the capacitive load is compensated by an inductive component. This component is made up of a free-running arrangement of the coaxial inner conductor and by a special indentation of the coaxial outer conductor or of a dielectric that may possibly be present at the point of transition. These indentations accommodate the substrate material used for the coplanar line, yet require relatively intensive machining work and are not therefore applicable when using commercially obtainable coaxial connectors (such as the Anritsu V115FCPW).

Furthermore, U.S. Pat. No. 5,570,068 discloses a “Coaxial-to-Coplanar-Waveguide Transmission Line connector, in which forming of the electric field from coaxial to coplanar is carried out within the coaxial line by specially machining a cavity in the coaxial outer conductor in the vicinity of the point of transition. The shape of this cavity accommodates the substrate material used for the coplanar line. Here, too, relatively intensive machining work is required and the arrangement can only be configured with difficulty when commercially obtainable coaxial connectors are being used.

### SUMMARY OF THE INVENTION

The object of the invention is to provide a device for connecting a coaxial line to a coplanar line, with the aid of which, when transmitting high bit rate data signals, the capacitive wire load that occurs at the point of connection between the coaxial line and the coplanar line can be compensated with relatively little technical work being required. The above object is achieved, starting from a device according to the features of the claims.

The essential feature of the device according to the invention is to be considered as being that the metallization layer has a recess beginning at the point of connection between the coaxial plug and the coplanar line and running approximately symmetrical to the coplanar inner conductor and tapering in the direction of the coplanar inner conductor as the distance from the point of connection increases. Advantageously, the capacitive line load is compensated by a recess in the metallization of the rear face of the coplanar line in the vicinity of the point of transition to the coaxial line. To avoid resonances, in the design according to the invention, the edges of the recess run approximately symmetrical to the coplanar inner conductor and the recess tapers in the direction of the coplanar inner conductor as the distance from the point of connection increases, that is, edges of the recess that run parallel to each other are thus avoided. Particularly good resonance characteristics are achieved, for example, by using a triangular-shaped recess.

In a further advantageous embodiment of the device according to the invention, when a metallic substrate carrier layer is used, an indentation that is congruent with the recess or larger is provided in the substrate carrier layer. Thus a short circuit in the recess is advantageously avoided.

Further advantageous embodiments of the device according to the invention are disclosed in the further claims.

### BRIEF DESCRIPTION OF THE DRAWINGS

Hereafter, embodiments of the method according to the invention are described in more detail with the aid of the attached drawings.

The drawings show:

FIG. 1 a device for connecting a coaxial plug to a coplanar line according to the prior art;

FIG. 2 by way of example, a diagram showing a top view onto the device according to the prior art shown in FIG. 1;

FIG. 3 by way of example, a device for connecting a coaxial plug to a coplanar line using the recess according to the invention;

FIG. 4 a section of the coplanar line that shows in more detail the geometry of the recess in the metallization layer according to the invention;

FIG. 5 a further embodiment of the device according to the invention by means of a side view of the device shown in FIG. 3 using a metallic substrate carrier layer;

FIG. 6 by means of a first and a second diagram, the reflection and transmission properties at the point of transition between the coaxial plug and the coplanar line.

### DETAILED DESCRIPTION OF THE INVENTION

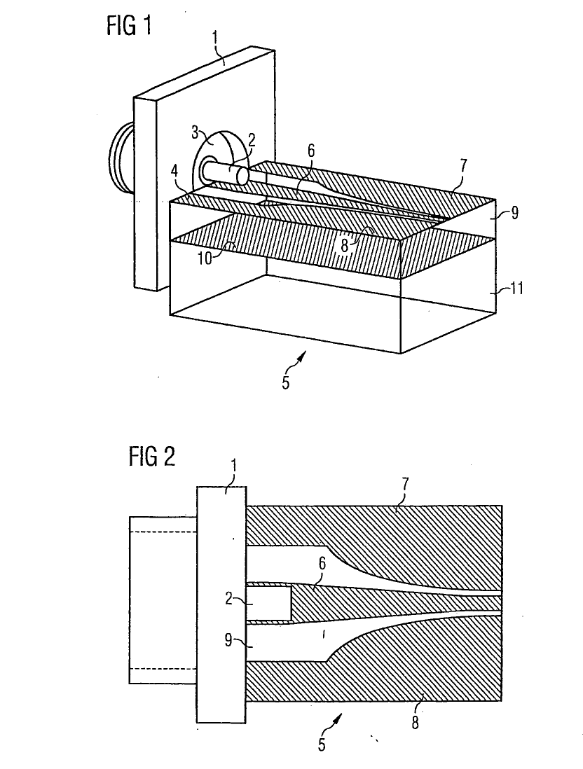

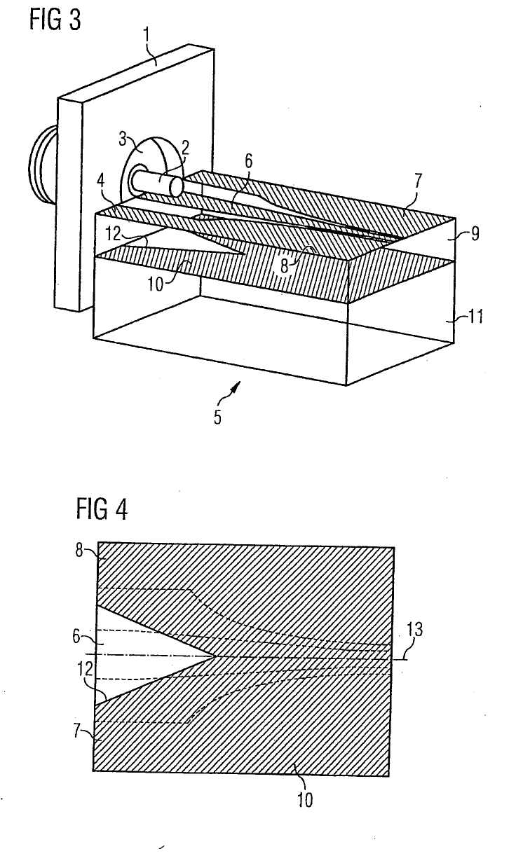

FIG. 3 shows, for instance, an embodiment of a device for connecting a coaxial line to a coplanar line, in particular for connecting a coaxial plug 1 to a coplanar line 5 for the transmission of high bit rate data signals. The coaxial line is shown in FIG. 3 for instance by the coaxial plug 1 and comprises, in a similar manner to the embodiment shown in FIG. 1, a coaxial inner conductor 2, a first dielectric layer 3 and a coaxial outer conductor 4. The coplanar line 5 consists of a conductor layer (6, 7, 8), followed by a second dielectric layer 9, a metallization layer 10 and a substrate carrier layer 11. The conductor layer (6, 7, 8) consists of a coplanar inner conductor 6 and a first and a second coplanar outer conductor 7, 8, the first and second coplanar outer conductor 7, 8 being separated from the coplanar inner conductor 6 by the second dielectric layer 9, for instance. The coaxial inner conductor 2 of the coaxial plug 1 is connected to the coplanar inner conductor 6 of the coplanar line 5 and the coaxial outer conductor 4 of the coaxial plug 1 is connected to the first and the second coplanar outer conductor 7, 8 of the coplanar line 5 and to the metallization layer 10 that is located on the rear face of the second dielectric layer 9. In the above arrangement, the metallization layer 10 and the first and the second coplanar outer conductor 7, 8 can be grounded. The second dielectric layer 9 of the coplanar line 5 is applied over the metallization layer 10 on a metallic substrate carrier layer 11, in a similar manner to that shown in FIG. 1.

To compensate for the capacitive line load that occurs when high bit rate data signals are transmitted at the connecting point between the coaxial line or coaxial plug 1 and the coplanar line 5, a recess 12 is provided according to the invention in the metallization layer 10. The recess runs approximately symmetrical to the coplanar inner conductor and tapers in the direction of the coplanar inner conductor as the distance from the point of connection increases. The thickness of the recess is equivalent to or greater than the thickness of the metallization layer 10. In the embodiment shown, the recess is triangular in shape, as a result of which a very good compensation effect can be achieved. The width of the recess 12 at the point of connection between the coaxial line or coaxial plug 1 and the grounded coplanar line 5 is approximately equivalent to the diameter of the first dielectric layer 3 which, for instance, encompasses the coaxial inner conductor 2 in a circular manner. Furthermore, the length of the recess 12 at the point of connection between the coaxial plug 1 and the grounded coplanar line 5 along the coplanar inner conductor 6 is greater than the zone where the coaxial inner conductor 2 overlaps with the coplanar inner conductor 6.

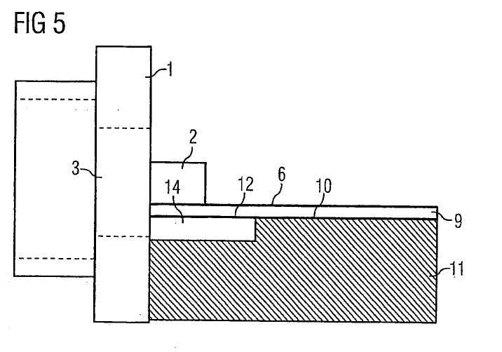

In FIG. 4, to make the geometry of the recess 12 clearer, the lower face of the metallization layer 10 is shown separately from the substrate carrier layer 11 as an area shown with dotted lines. Additionally, the outline of the coplanar inner conductor 6 and of the first and the second coplanar outer conductor 7, 8, which are arranged according to the metallization layer 10 are indicated with the aid of dotted lines. The recess 12 is shaped like an isosceles triangle, with the apex of the isosceles triangle resting, for instance, on the central line 13 of the coplanar inner conductor 6 in the top view.

FIG. 5 shows, in diagram form, a side view of the device depicted in FIG. 3 for connecting a coaxial plug 1 to a coplanar line 5. In contrast to the embodiment shown in FIG. 3, the substrate carrier layer 11 has, at the point of contact with the recess 12 in the metallization layer 10, an indentation 14, which is rectangular, for instance. The area of the indentation 14 is at least congruent with that of the recess 12, so that a short circuit can be avoided at the location of the recess 12 when a metallic substrate carrier layer 11 is used. In the above arrangement, the geometrical shape of the indentation 14 is immaterial; it is merely used for isolation at the recess 12. It is preferable, however, to use indentations 14, whose edges do not run parallel to each other, that is, the width and/or the height of the indentation 14 in the substrate carrier layer 11 tapers in a direction along the coplanar inner conductor 6 as the distance from the point of connection increases.

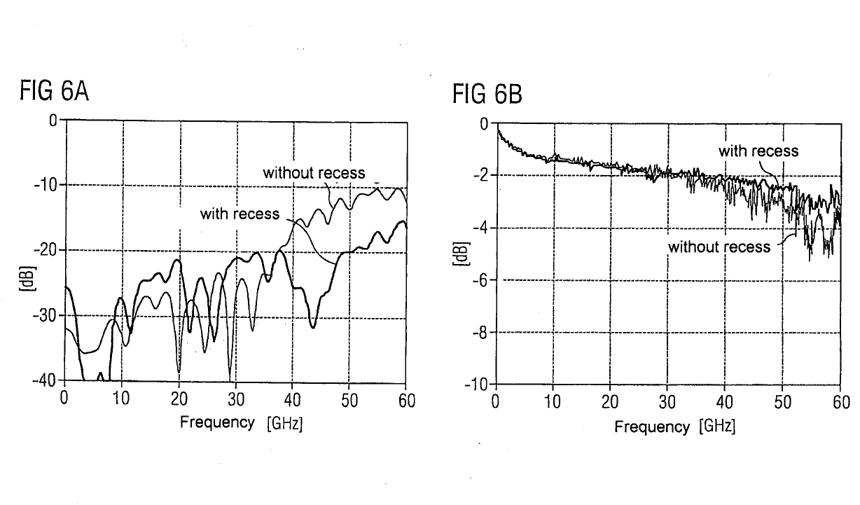

FIG. 6 shows, by means of a first and a second diagram, FIG. 6a/b, the reflection properties and transmission properties on the device shown in FIG. 3 or at the transition between the coaxial plug 1/coplanar line 5 in each case with and without the recess 12. The improvement achieved in the metallization layer 10 by using the recess 12 is clearly evident at frequencies above 40 GHz. For instance, in the first diagram 6a, an improvement in the reflection properties of up to 10 dB is detectable at frequencies above 40 GHz. The transmission properties shown in the second diagram FIG. 6b improve by 1 dB or more at frequencies above 40 GHz.

A further advantage of the device according to the invention is that commercial coaxial pin-and-socket connectors can be used for the implementation thereof, irrespective of the substrate carrier layer 11, the coplanar line 5 and of the line geometry of said coplanar line 5.

1-10. (canceled)

11. A device for connecting a coaxial line to a coplanar line for transmission of high bit rate data signals, comprising:
a coaxial line, comprising:
a coaxial inner conductor,
a coaxial outer conductor,
a first dielectric layer encompassing the coaxial inner conductor and surrounded by the coaxial outer conductor;
a coplanar line, comprising:
a coplanar inner conductor,
first and second coplanar outer conductors which transition into a parallel course,
a second dielectric layer separating the first and second coplanar outer conductors from the coplanar inner conductor, comprising:
a front face comprising the coplanar inner conductor and the first and second coplanar outer conductors,
a rear face comprising a metallization layer and a substrate carrier layer;
a recess located at the metallization layer which begins at a point of connection between the coaxial line and the coplanar line and extends along the coplanar inner conductor and tapers in a direction of the coplanar inner conductor as a distance from the point of connection increases,
wherein the coaxial inner conductor is connected to the coplanar inner conductor and the coaxial outer conductor is connected to the first and second coplanar outer conductors.

12. The device as claimed in claim 11, wherein the recess extends symmetrically to the coplanar inner conductor.

13. The device as claimed in claim 11, wherein an indentation is provided in the substrate carrier layer and is congruent with the recess at the metallization layer or has a greater area.

14. The device as claimed in claim 13, wherein a width and height of the indentation in the substrate carrier layer taper in the direction of the coplanar inner conductor as the distance from the point of connection increases.

15. The device as claimed in claim 11, wherein a width of the recess at the point of connection between the coaxial line and the coplanar line is approximately equivalent to a diameter of the first dielectric layer which circularly encompasses the coaxial inner conductor.

16. The device as claimed in claim 11, wherein the recess is triangular.

17. The device as claimed in claim 11, wherein a length of the recess at the point of connection between the coaxial line and the coplanar line along the coplanar inner conductor is greater than a zone where the coaxial inner conductor overlaps with the coplanar inner conductor.

18. The device as claimed in claim 11, wherein the first dielectric layer is ambient air and the second dielectric layer is a ceramic material.

19. The device as claimed in claim 11, wherein the first and second coplanar outer conductors of the coplanar line are connected to an earth potential.

20. The device as claimed in claim 11, wherein the coaxial line is a coaxial plug and is connected to the coplanar line.

21. The device as claimed in claim 11, wherein the device is a communication device.
